(19) United States
(12) Patent Application Publication
(10) Pub. No.: US 2026/0371042 A1
(43) Pub. Date: Nov. 19, 2026

(54) SYSTEM AND METHOD FOR PEOPLE COUNTING BASED ON WIRELESS SIGNALS

(71) Applicant: DELTA ELECTRONICS, INC., Taoyuan City (TW)

(72) Inventors: Chia-Lung LIU, Taoyuan City (TW); Chun-Yi CHEN, Taoyuan City (TW); Ting-Wu HO, Taoyuan City (TW); Kuei-Li HUANG, Taoyuan City (TW); Hsin-Chih WANG, Taoyuan City (TW); Kuo-Hao SUNG, Taoyuan City (TW)

(21) Appl. No.: 19/290,706

(22) Filed: Aug. 5, 2025

(30) Foreign Application Priority Data
May 19, 2025 (CN) 202510641773.6

(51) Int. Cl. H04W 4/38; G06F 30/20; H04B 17/318

(52) U.S. Cl. CPC H04W 4/38; G06F 30/20; H04B 17/318

(57) ABSTRACT

A system for people counting includes an off-line simulation module and a real-time detection module. The off-line simulation module simulates the occurrence probability of various numbers of people in the environment relative to the crossing numbers in the observation time window and to establish an estimated people table. The real-time detection module performs actions of: extracting a crossing event time sequence of a sensing path relative to the at least one set of sensor when a person moves in the environment according to the signal strength; using the observation time window to count at least one crossing number in the crossing event time sequence relative to the observation time window at at least one detection time point; querying the estimated people table to obtain an actual number of people in the environment according to the at least one crossing number.

### BACKGROUND

### Technical Field

The present disclosure relates to a technology of people counting, and more particularly to a system and a method for people counting based on wireless signals.

### Description of Related Art

The statements in this section merely provide background information related to the present disclosure and do not necessarily constitute prior art.

Current people sensing technology can detect the number of people passing through a specific passage or within a sensing range, which may be used in stores, shopping malls, and public transportation. The detected number of people can be used to analyze the flow of people and facilitate the planning of personnel movement trajectories or traffic routes.

Common people counting systems include infrared beams, image recognition, and smart devices to detect and count people. However, these common people counting systems today each have their own shortcomings that need to be addressed. For example, systems based on infrared beams are limited by the installation location of the infrared beam sensor (which needs to be installed at a lower location), which may result in low accuracy of detection results due to poor sensing location. Systems based on image recognition are limited by higher camera costs, large network bandwidth, and complex calculations. Systems based on smart devices cannot count people in the environment who do not carry any smart devices with Wi-Fi capabilities.

### SUMMARY

In order to achieve the above-mentioned objective, the present disclosure provides a system for people counting based on wireless signals applied in an environment. The system for people counting includes an off-line simulation module and a real-time detection module. The off-line simulation module executes a simulation algorithm; the simulation algorithm performs simulation based on an environmental parameter of the environment and generate an estimated people table. The estimated people table records occurrence probabilities of various people in the environment relative to various crossing numbers within an observation time window. The real-time detection module includes at least one set of sensor and a people counting device. The at least one set of sensor is disposed in the environment and includes a transmitting terminal and a receiving terminal. The transmitting terminal transmits a wireless signal and the receiving terminal receives the wireless signal so as to measure a signal strength of the wireless signal. The people counting device receives the signal strength measured by the at least one set of sensor, and performs the following actions. Action (a): extracting a crossing event time sequence of a sensing path relative to the at least one set of sensor when a person moves in the environment according to the signal strength, wherein the crossing event time sequence records multiple time-based actual crossing events. Action (b): using the observation time window to count at least one crossing number in the crossing event time sequence relative to the observation time window at at least one detection time point. Action (c): querying the estimated people table to obtain an actual number of people in the environment according to the at least one crossing number, wherein the people counting device uses the number of people in the estimated people table that meets the at least one crossing number and has the highest occurrence probability as the actual number of people.

In order to achieve the above-mentioned objective, the present disclosure provides a method for people counting based on wireless signals applied to a system for people counting. The system for people counting includes an off-line simulation module and a real-time detection module. The real-time detection module includes a people counting device and at least one set of sensor disposed in an environment. The method includes steps of: step (a): executing, by the off-line simulation module, a simulation algorithm based on an environmental parameter of the environment to generate an estimated people table, wherein the estimated people table records occurrence probabilities of various people in the environment relative to various crossing numbers within an observation time window; step (b): sensing, by the set of sensor, a wireless signal on a sensing path and measuring a signal strength of the wireless signal; step (c): extracting, by the people counting device, a crossing event time sequence relative to the sensing path when a person moves in the environment according to the signal strength, wherein the crossing event time sequence records multiple time-based crossing events; step (d): using, by the people counting device, the observation time window to count at least one crossing number in the crossing event time sequence relative to the observation time window at at least one detection time point; step (e): querying, by the people counting device, the estimated people table to obtain an actual number of people in the environment according to the at least one crossing number, wherein the people counting device uses the number of people in the estimated people table that meets the at least one crossing number and has the highest occurrence probability as the actual number of people.

Compared with the prior art, the present disclosure can simulate the actual environment and actual people in advance to generate an estimated people table, and generate a crossing event time sequence according to the signal strength detected in the actual environment, and then use an observation time window of a specific length to obtain crossing numbers at each time point, and use the estimated people table to convert multiple crossing numbers into the actual number of people in the actual environment. Therefore, the present disclosure is to provide a people counting system and method based on wireless signals to solve the problems of the prior art that the sensing position is easily inaccurate, the setting cost is wasted, and a large amount of computing resources are consumed.

It is to be understood that both the foregoing general description and the following detailed description are exemplary, and are intended to provide further explanation of the present disclosure as claimed. Other advantages and features of the present disclosure will be apparent from the following description, drawings, and claims.

### BRIEF DESCRIPTION OF DRAWINGS

The present disclosure can be more fully understood by reading the following detailed description of the embodiment, with reference made to the accompanying drawing as follows: FIG. 1 is a block diagram of a people counting system based on wireless signals according to some embodiments of the present disclosure.

FIG. 2A to FIG. 2D are schematic diagrams of environments according to some embodiments of the present disclosure.

FIG. 3A is a flowchart of a method for counting people based on wireless signals in some embodiments of the present disclosure.

FIG. 3B is a flowchart of a simulation algorithm in some embodiments of the present disclosure.

FIG. 4A and FIG. 4B are schematic plan views of a simulation environment in some embodiments of the present disclosure.

FIG. 5 is a schematic diagram of multiple crossing event simulation time sequences in some embodiments of the present disclosure.

FIG. 6 is a schematic diagram of an observation time window moving on a plurality of overlapping time sequences in some embodiments of the present disclosure.

FIG. 7A is a flowchart of a plurality of sub-steps included in one step of a method for counting people based on wireless signals in some embodiments of the present disclosure.

FIG. 7B is a schematic diagram of converting signal strength into a crossing event time sequence in some embodiments of the present disclosure.

FIG. 8 is a flowchart of a plurality of sub-steps included in another step of a method for counting people based on wireless signals in some embodiments of the present disclosure.

FIG. 9 is a schematic diagram of a crossing event time sequence in some embodiments of the present disclosure.

FIG. 10 is a flowchart of a plurality of further steps of a method for counting people based on wireless signals in some embodiments of the present disclosure.

FIG. 11 is a schematic diagram of a crossing event time sequence in some other embodiments of the present disclosure.

FIG. 12 is a schematic diagram of a crossing event time sequence in some other embodiments of the present disclosure.

FIG. 13 is a flowchart of a plurality of further steps of a method for counting people based on wireless signals in some other embodiments of the present disclosure.

FIG. 14 is a schematic diagram of a crossing event time sequence in some other embodiments of the present disclosure.

FIG. 15 is a diagram of a relationship between a people change index and a plurality of detection time points in some embodiments of the present disclosure.

### DETAILED DESCRIPTION

Reference will now be made to the drawing figures to describe the present disclosure in detail. It will be understood that the drawing figures and exemplified embodiments of present disclosure are not limited to the details thereof.

Please refer to FIG. 1, which shows a block diagram of a people counting system based on wireless signals according to some embodiments of the present disclosure. As shown in FIG. 1, in this embodiment, a people counting system 100 based on wireless signals includes an off-line simulation module 110 and a real-time detection module 120.

In this embodiment, the off-line simulation module 110 is used to execute the simulation algorithm. The subsequent paragraphs will further describe the simulation algorithm, which will not be repeated here. In some embodiments, the off-line simulation module 110 may be connected to the real-time detection module 120. In some embodiments, the off-line simulation module 110 may be implemented by any processing device (e.g., a desktop computer) or server (e.g., a cloud server) for performing calculations.

In this embodiment, the real-time detection module 120 includes at least one set of sensors 121(1)-121(s), 122(1)-122(t) and a people counting device 123. The at least one set of sensors 121(1)-121(s), 122(1)-122(t) is disposed in an environment and includes a transmitting terminal for continuously transmitting wireless signals and a receiving terminal for continuously receiving wireless signals. In some embodiments, the sensors 121(1)-121(s) may be transmitting terminals, and the sensors 122(1)-122(t) may be receiving terminals, wherein s and t may be any positive integers. The present disclosure transmits wireless signals (such as Wi-Fi signals) through the transmitting terminals, and receives the wireless signals through the receiving terminals. In an environment with wireless signals (such as Wi-Fi electromagnetic waves), when people move around in the environment, the signal distribution of the wireless signals will be affected, and when the number of people walking is different, the types of impact also vary. This disclosure uses the change of wireless signals to estimate the number of people in the environment through this impact.

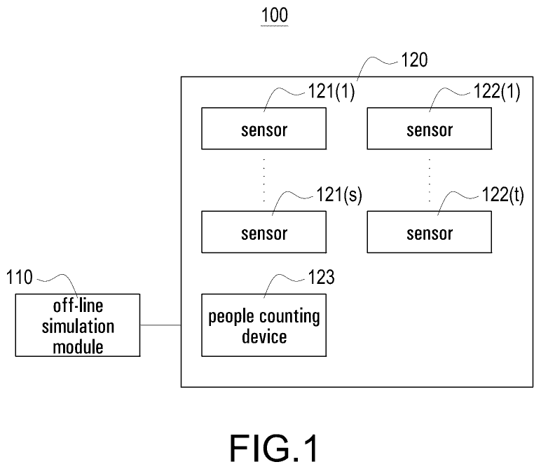

The following describes a set of sensors using a practical example. Please refer to FIG. 2A to FIG. 2D, which show schematic diagrams of environments according to some embodiments of the present disclosure. As shown in FIG. 2A, in the present embodiment, the environment F1 includes a set of sensors, and the set of sensors includes a sensor 121(1) as a transmitting terminal and a sensor 122(1) as a receiving terminal. In the environment F1, the sensor 121(1) is at a distance from the sensor 122(1), and the sensor 121(1) continuously transmits a wireless signal to the sensor 122(1) in a directional manner. There may be moving persons P1-Po in the environment F1, where o may be any positive integer. In particular, although a set of sensors including a single transmitting terminal and a single receiving terminal is used as an example, in actual applications, the real-time detection module 120 may include multiple sets of sensors, each of which includes a transmitting terminal and a receiving terminal.

As shown in FIG. 2B, in this embodiment, the environment F1 includes a set of sensors, and the set of sensors includes a sensor 121(1) as a transmitting terminal and multiple sensors 122(1)-122(u) as receiving terminals, where u may be any positive integer greater than 1. In the environment F1, the sensor 121(1) is a distance from the sensors 122(1)-122(u), and the sensor 121(1) continuously transmits wireless signals to the sensors 122(1)-122(u) in a directional manner. There may also be moving persons P1-Po in the environment F1, where o may be any positive integer. In particular, although a set of sensors including a single transmitting terminal and multiple receiving terminals is used as an example, in actual applications, the real-time detection module 120 may include more sets of sensors.

As shown in FIG. 2C, in this embodiment, the environment F1 includes a set of sensors, and the set of sensors includes a plurality of sensors 121(1)-121(v) as transmitting terminals and a sensor 122(1) as a receiving terminal, where v may be any positive integer greater than 1. In the environment F1, the sensors 121(1)-121(v) are at a distance from the sensor 122(1), and the sensors 121(1)-121(v) respectively continuously transmit wireless signals to the sensor 122(1) in a directional manner. There may also be moving persons P1-Po in the environment F1, where o may be any positive integer. In particular, although a set of sensors including a plurality of single transmitting terminals and a single receiving terminal is taken as an example, in actual applications, the real-time detection module 120 may include more sets of sensors.

As shown in FIG. 2D, in this embodiment, the environment F1 includes a set of sensors, and the set of sensors includes a sensor 121(1) as a transmitting terminal and a sensor 122(1) as a receiving terminal. The difference from the embodiment of FIG. 2A is that the sensor 121(1) and the sensor 122(1) are disposed at the same position in the environment F1 (for example, the transmitting terminal and the receiving terminal belong to the same sensing device). The sensor 121(1) continuously transmits wireless signals in an omnidirectional manner, and the sensor 122(1) receives wireless signals transmitted by the sensor 121(1).

In some embodiments, the wireless signal may be implemented by any radio electromagnetic wave signal (e.g., Wi-Fi signal). In some embodiments, the sensors 121(1)-121(s) as the transmitting terminal may be implemented by any wireless transmitter (e.g., Wi-Fi transmitter). In some embodiments, the sensors 122(1)-122(t) as the receiving terminal may be implemented by any wireless receiver with signal strength detection function (e.g., Wi-Fi receiver). In some embodiments, the environment F1 generally refers to any place where people often gather or pass by (e.g., a department store).

In this embodiment, the people counting device 123 continuously receives the signal strength of the wireless signal measured by at least one set of sensors 121(1)-121(s), 122(1)-122(t) to perform the people counting method based on wireless signals described in the subsequent paragraphs. In some embodiments, the signal strength may be implemented by any index used to measure the energy size of the signal (for example, a received signal strength indicator (RSSI)). In some embodiments, the people counting device 123 may also be implemented by any processing device (for example, a desktop computer) or server (for example, a cloud server) used to perform calculations.

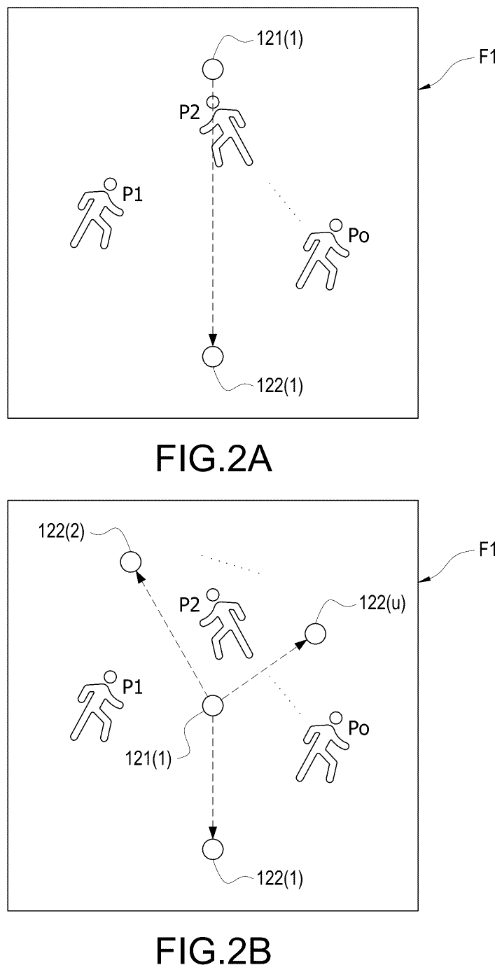

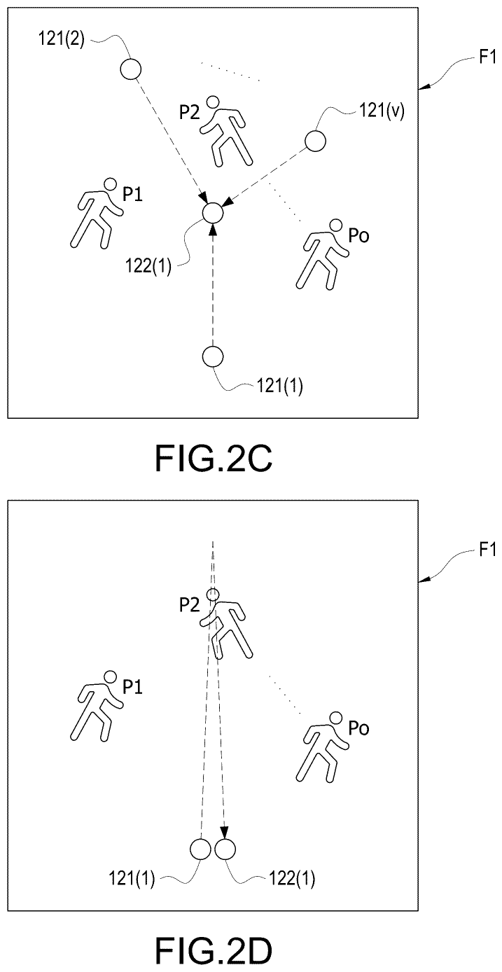

The following further describes the method for counting people based on wireless signals. Please refer to FIG. 3A, which shows a flowchart of a method for counting people based on wireless signals in some embodiments of the present disclosure. This method is applicable to the people counting system 100 based on wireless signals in FIG. 1. As shown in FIG. 3A, the method for counting people based on wireless signals includes steps S310 to S350.

In step S310, the off-line simulation module 110 executes a simulation algorithm based on the environmental parameters of the environment F1 to generate an estimated people table. In this embodiment, the estimated people table records the occurrence probability of various numbers of people (e.g., 1 person, 2 people, . . . n people, etc.) in the environment F1 relative to various crossing numbers (e.g., 1 time, 2 times, . . . n times, etc.) within an observation time window of a preset length (e.g., 5 seconds).

In some embodiments, the environmental parameters include environmental size, sensor location, simulation time, simulated people limit, observation time window length, sampling frequency, walking speed, and turning probability. The environmental size indicates the area of the environment F1 to be simulated, for example, a space of 10 m*7 m. The sensor location indicates the location coordinates (for example, GPS coordinates) of at least one set of sensors 121(1)-121(s), 122(1)-122(t) in the environment F1. The simulation time indicates the time length for simulating the movement of people in the environment F1 (for example, 36 hours). The simulated people limit indicates the maximum number of people that can exist in the environment F1. For example, since each person usually requires a minimum activity space of 2.297 square meters, the result of dividing the area of the environment F1 by 2.297 square meters and taking a ceiling operation can be regarded as the simulated people limit.

The observation time window length indicates the length of the observation time window described in the subsequent paragraphs (e.g., 5 seconds). The sampling frequency indicates how often the position of the person is recorded each time (e.g., once per second). The walking speed indicates how fast an average person typically walks (e.g., 1.2 m/s). The turning probability indicates the probability that the average person will turn while walking (e.g., 0.2).

The simulation algorithm is further described below. Please refer to FIG. 3B, which shows a flowchart of a simulation algorithm in some embodiments of the present disclosure. As shown in FIG. 3B, the simulation algorithm includes steps S311 to S317.

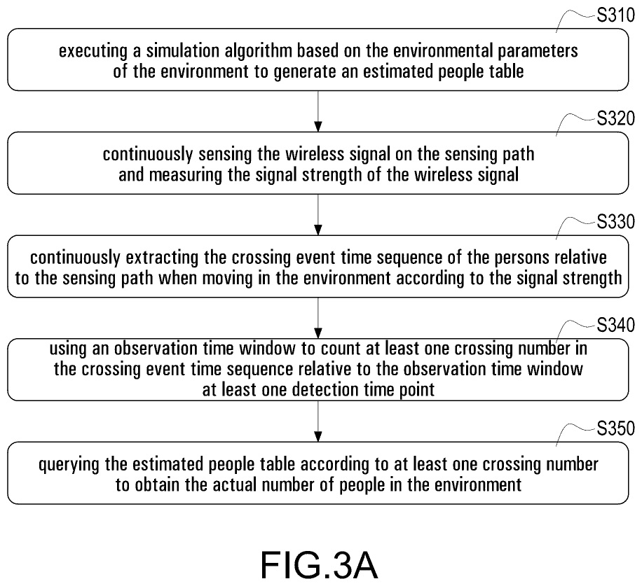

In step S311, the off-line simulation module 110 generates a simulation environment (such as the simulation environment F2 shown in FIG. 4A and FIG. 4B) based on the environment size and the sensor position, and generates multiple virtual persons corresponding to the simulated people limit (for example, when the simulated people limit is 3, the number of virtual persons generated is also 3).

In some embodiments, the simulation environment is used to simulate an actual environment F1 with a specific environment size, and may be a virtual field in a two-dimensional or three-dimensional space. In some embodiments, the simulation environment is provided with at least one set of virtual sensors (including a virtual transmitting terminal and a virtual receiving terminal) generated based on the sensor position, wherein the virtual transmitting terminal and the virtual receiving are used to simulate at least one set of sensors 121(1)-121(s), 122(1)-122(t) in this environment F1. There is at least one virtual signal path between the virtual transmitting terminal and at least one virtual receiving terminal to simulate a transmission path of an actual wireless signal continuously transmitted by the transmitting terminal and received by the receiving terminal. In some embodiments, multiple virtual persons are used to simulate actual persons in this environment F1.

In step S312, the off-line simulation module 110 randomly generates virtual moving paths for each virtual person in the simulation environment based on the preset walking speed and turning probability, and sequentially moves each virtual person along the respective virtual moving paths at the walking speed according to the simulation time (i.e., simulating one virtual person walking in the simulation environment at a time). In some embodiments, the virtual moving path is used to simulate the moving path of an actual person in the environment F1.

The simulation of the simulation environment is described below with a practical example. Please refer to FIG. 4A and FIG. 4B, which are schematic plan views of a simulation environment in some embodiments of the present disclosure. As shown in FIG. 4A, the simulation environment F2 has a simulated virtual transmitting terminal VTx1 and a virtual receiving terminal VRx1, and a virtual signal path VL1 is provided between the virtual transmitting terminal VTx1 and the virtual receiving terminal VRx1, that is, the off-line simulation module 110 performs a simulation program in which the virtual transmitting terminal VTx1 transmits a wireless signal along the virtual signal path VL1 and the virtual receiving terminal VRx1 receives the signal. In an embodiment in which the number of virtual persons is 2, the off-line simulation module 110 can randomly generate a virtual moving path WP1 of the virtual person VP1 in the simulation environment F2 based on the walking speed and the turning probability, and randomly generate a virtual moving path WP2 of the virtual person VP2 in the simulation environment F2 based on the same or different walking speeds and the same or different turning probabilities. Afterward, the off-line simulation module 110 may move the virtual person VP1 along the virtual moving path WP1 at a walking speed in a time sequence corresponding to the simulation time. After completing the simulation of the walking of the virtual person VP1, the off-line simulation module 110 may move the virtual person VP2 along the virtual moving path WP2 at the walking speed in another time sequence corresponding to the simulation time.

As shown in FIG. 4B, the simulation environment F2 has simulated virtual transmitting terminals VTx1-VTx2 and virtual receiving terminals VRx1-VRx2. There is a virtual signal path VL1 between the virtual transmitting terminal VTx1 and the virtual receiving terminal VRx1, and there is a virtual signal path VL2 between the virtual transmitting terminal VTx2 and the virtual receiving terminal VRx2. In the embodiment where the number of virtual persons is 2, the off-line simulation module 110 can randomly generate a virtual moving path WP1 of the virtual person VP1 in the simulation environment F2 based on the walking speed and the turning probability, and randomly generate a virtual moving path WP2 of the virtual person VP2 in the simulation environment F2 based on the walking speed and the turning probability. Furthermore, in different time sequences, the virtual persons VP1, VP2 are respectively moved along the virtual moving paths WP1, WP2 at the walking speed.

In particular, although the virtual transmitting terminals VTx1-VTx2, virtual receiving terminals VRx1-VRx2, and virtual persons VP1-VP2 are used as examples here, in actual applications, the off-line simulation module 110 can generate different configurations of virtual transmitting terminals, virtual receiving terminals, and virtual persons according to the environmental parameters of the actual environment F1, and is not limited to those shown in FIG. 4A and FIG. 4B.

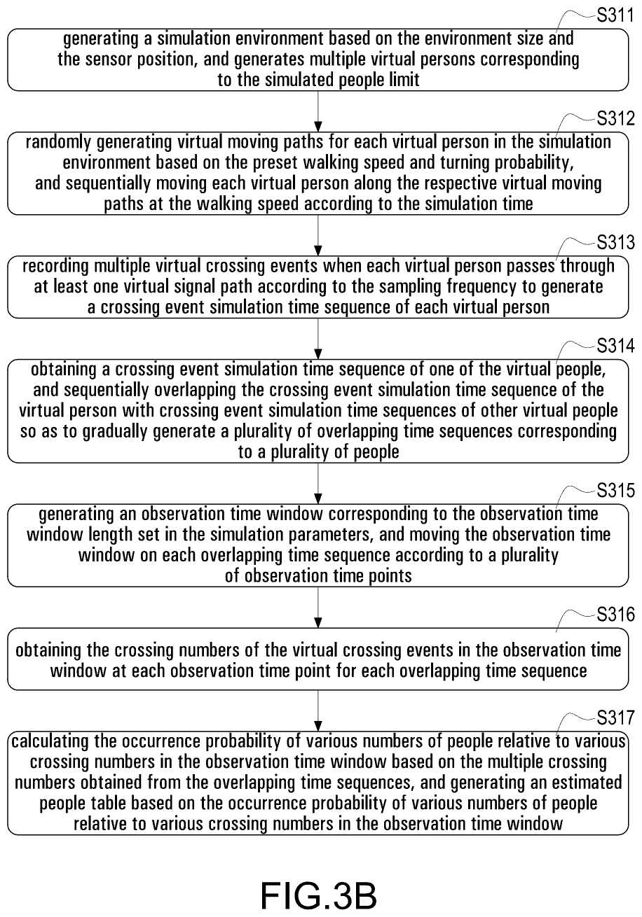

As shown in FIG. 3B, in step S313, the off-line simulation module 110 can record multiple virtual crossing events when each virtual person passes through at least one virtual signal path according to the sampling frequency to generate a crossing event simulation time sequence of each virtual person, e.g., the crossing event simulation time sequence E1 of FIG. 5 described in the subsequent paragraphs.

In some embodiments, the off-line simulation module 110 may generate multiple position points for each virtual person on the virtual moving path according to the sampling frequency. For example, for the virtual moving path WP1 of FIG. 4A and FIG. 4B, the off-line simulation module 110 records the position of the moving virtual person VP1 as a position point per second, and records the position of the moving virtual person VP2 as a position point per second for the virtual moving path WP2. Afterward, the off-line simulation module 110 may use any position point overlapping with at least one virtual signal path of each virtual person as a virtual crossing event (i.e., representing that the virtual person crossed a virtual signal path during movement), and generate a crossing event simulation time sequence of each virtual person according to all virtual crossing events of each virtual person and multiple virtual occurrence times of all virtual crossing events of each virtual person, wherein each virtual occurrence time indicates the time point at which the corresponding virtual crossing event occurred in the simulation program.

Taking FIG. 4A as an example, it is assumed that one of the position points of the virtual person VP1 overlaps with the virtual signal path VL1, the off-line simulation module 110 can use the position point (for example, the first position point) where the virtual person VP1 overlaps with the virtual signal path VL1 as the virtual crossing event CP1 of the virtual person VP1, and record the time when the virtual person VP1 moves to the first position point as the virtual occurrence time of the virtual crossing event CP1.

It is assumed that one of the positions of the virtual person VP2 overlaps with the virtual signal path VL1, the off-line simulation module 110 may use the position point (e.g., the second position point) where the virtual person VP2 overlaps with the virtual signal path VL1 as the virtual crossing event CP2 of the virtual person VP2, and record the time when the virtual person VP2 moves to the second position point as the virtual occurrence time of the virtual crossing event CP2. In particular, based on the simulation results, each virtual person may cross one or more virtual signal paths in the simulation environment F2 zero times, once, or multiple times, and is not limited to the above.

Taking FIG. 4B as an example, it is assumed that two position points of the virtual person VP1 during movement overlap with the virtual signal path VL1, and all position points of the virtual person VP1 during movement do not overlap the virtual signal path VL2, the off-line simulation module 110 can use the two position points (for example, the first position point and the second position point) where the virtual person VP1 overlaps with the virtual signal path VL1 as virtual crossing events CP1-CP2 of the virtual person VP1, and record the time when the virtual person VP1 moves to the first position point and the second position point as the virtual occurrence time of the virtual crossing events CP1-CP2.

It is assumed that one of the position points of the virtual person VP2 during movement overlaps with the virtual signal path VL1, and another position point of the virtual person VP2 during movement overlaps with the virtual signal path VL2, the off-line simulation module 110 can use the position point (for example, the third position point) where the virtual person VP2 overlaps with the virtual signal path VL1 and the position point (for example, the fourth position point) where the virtual person VP2 overlaps with the virtual signal path VL2 as virtual crossing events CP3-CP4 of the virtual person VP2, and record the time when the virtual person VP1 moves to the third position point and the fourth position point as the virtual occurrence time of the virtual crossing events CP3-CP4.

The following is a practical example to illustrate the crossing event simulation time sequence. Please refer to FIG. 5, which shows a schematic diagram of multiple crossing event simulation time sequences in some embodiments of the present disclosure. As shown in FIG. 5, it is assumed that the simulated people limit is 3, the crossing event simulation time sequence E1 of the first simulated person indicates all virtual crossing events of the first simulated person (i.e., all impulses on the crossing event simulation time sequence E1) and the virtual occurrence time of each virtual crossing event (i.e., multiple time points corresponding to all impulses on the crossing event simulation time sequence E1). The crossing event simulation time sequence E2 of the second simulated person indicates all virtual crossing events of the second simulated person (i.e., all impulses on the crossing event simulation time sequence E2) and the virtual occurrence time of each virtual crossing event (i.e., multiple time points corresponding to all impulses on the crossing event simulation time sequence E2). The crossing event simulation time sequence E3 of the third simulated person indicates all virtual crossing events of the third simulated person (i.e., all impulses on the crossing event simulation time sequence E3) and the virtual occurrence time of each virtual crossing event (i.e., multiple time points corresponding to all impulses on the crossing event simulation time sequence E3).

As shown in FIG. 3B, in step S314, the off-line simulation module 110 obtains a crossing event simulation time sequence of one of the virtual people, and sequentially overlaps the crossing event simulation time sequence of the virtual person with crossing event simulation time sequences of other virtual people so as to gradually generate multiple overlapping time sequences corresponding to a plurality of people (e.g., two people, three people, . . . , n people), wherein the number of the plurality of people is not greater than the simulated people limit.

In some embodiments, when a time interval between any two virtual crossing events in each overlapping time sequence is less than the interval threshold, the off-line simulation module 110 deletes one of the two virtual crossing events. In some embodiments, the total duration of all crossing event simulation time sequences and all overlapping time sequences is equal to the simulation time.

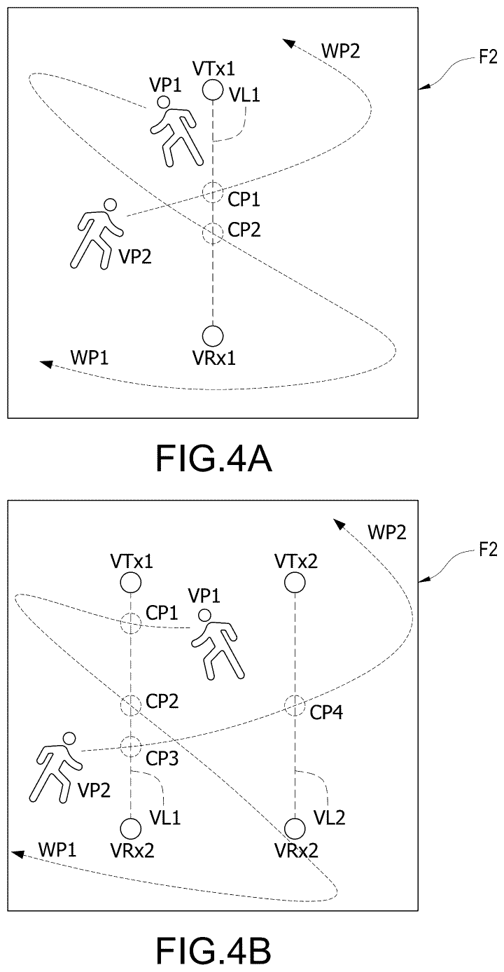

Taking FIG. 5 as an example. The off-line simulation module 110 may obtain the crossing event simulation time sequence E1 (i.e., the first overlapping time as the overlapping time sequence corresponding to one virtual person (i.e., the first overlapping time sequence CE1 of FIG. 6), and then overlap the crossing event simulation time sequence E1 with the crossing event simulation time sequence E2 to generate the overlapping time sequence (i.e., the second overlapping time sequence CE2 of FIG. 6) corresponding to two virtual persons, and then overlap the second overlapping time sequence with the crossing event simulation time sequence E3 to generate the overlapping time sequence (i.e., the third overlapping time sequence CE3 of FIG. 6) corresponding to three virtual persons, and so on.

In order to clearly explain how to delete virtual crossing events that are too close, the third overlapping time sequence CE3 is used as an example. The off-line simulation module 110 can determine that there are two adjacent virtual crossing events 510-520 and another two adjacent virtual crossing events 530-540 in the third overlapping time sequence CE3 whose time interval is less than the interval threshold TI1. Therefore, the off-line simulation module 110 deletes the virtual crossing events 520, 540 and only retains the virtual crossing events 510, 530.

As shown in FIG. 3B, in step S315, the off-line simulation module 110 generates an observation time window corresponding to the observation time window length set in the simulation parameters, and moves the observation time window on each overlapping time sequence according to multiple observation time points.

In some embodiments, for each overlapping time sequence, the off-line simulation module 110 can use the last end of the observation time window (i.e., the time point at which the observation ends) as a reference to sequentially move the observation time window to multiple observation time points. In some embodiments, there is a specific time interval (e.g., 1 second) between multiple observation time points, and this time interval is determined by a system sensitivity of the off-line simulation module 110 (i.e., the precision of the detection). In some embodiments, the observation time point disposed at the front is equal to the observation time window length, and the observation time point disposed at the end is equal to the simulation time. In particular, the moving end point of the observation time window may be the end point of the simulation data (i.e., the time point corresponding to the last simulation data).

In step S316, for each overlapping time sequence, the off-line simulation module 110 obtains the crossing numbers of the virtual crossing events in the observation time window at each observation time point.

In some embodiments, each crossing number indicates the total number of all virtual crossing events in the observation time window at the corresponding observation time point.

The following is a practical example to illustrate the crossing numbers. Please refer to FIG. 6, which shows a schematic diagram of an observation time window moving on multiple overlapping time sequences in some embodiments of the present disclosure, that is, a schematic diagram of the observation time window VW moving on the first overlapping time sequence CE1 (corresponding to one virtual person), the second overlapping time sequence CE2 (corresponding to two virtual persons), and the third overlapping time sequence CE3 (corresponding to three virtual persons). As shown in FIG. 6, the off-line simulation module 110 takes the last end of the observation time window VW corresponding to a specific observation time window length (e.g., 5 seconds) as a reference and moves the observation time window VW to the first observation time point 610 of the first overlapping time sequence CE1. Therefore, on the first overlapping time sequence CE1, the off-line simulation module 110 can calculate the number of all virtual crossing events in the observation time window VW at the observation time point 610 to generate the crossing numbers (i.e., 4 times). In this embodiment, the crossing numbers represent the numbers that, when there is one virtual person in the simulation environment F2, the virtual person crosses the one or more virtual signal paths within the time interval indicated by the observation time window VW.

Afterward, the off-line simulation module 110 moves the last end of the observation time window VW to the second observation time point 620 of the first overlapping time sequence CE1. Therefore, on the first overlapping time sequence CE1, the off-line simulation module 110 can calculate the number of all virtual crossing events in the observation time window VW at the second observation time point 620 to generate the crossing numbers (i.e., 3 times).

Afterward, the off-line simulation module 110 moves the last end of the observation time window VW to the third observation time point 630 of the first overlapping time sequence CE1. Therefore, on the first overlapping time sequence CE1, the off-line simulation module 110 can calculate the number of all virtual crossing events in the observation time window VW at the third observation time point 630 to generate the crossing numbers (i.e., 4 times).

In addition, the off-line simulation module 110 can calculate the three crossing numbers corresponding to the first observation time point 610 to the third observation time point 630 from the second overlapping time sequence CE2 in the same method (in the embodiment of FIG. 6, 6 times, 5 times, and 4 times, respectively). The off-line simulation module 110 can also calculate the three crossing numbers corresponding to the first observation time point 610 to the third observation time point 630 from the third overlapping time sequence CE3 in the same method (i.e., 6 times, 6 times, and 7 times, respectively). In the embodiment of observing the second overlapping time sequence CE2, the crossing numbers represent the number of times when there are two virtual persons in the simulation environment F2, and the two virtual persons cross the one or more virtual signal paths within the time interval indicated by the observation time window VW. In the embodiment of observing the third overlapping time sequence CE3, the crossing numbers represent the number of times when there are three virtual persons in the simulation environment F2, and the three virtual persons cross the one or more virtual signal paths within the time interval indicated by the observation time window VW, and so on.

In particular, in some embodiments, the environmental parameters may also include at least one alternative observation time window length, and the off-line simulation module 110 may generate at least one alternative observation time window corresponding to the alternative observation time window length. In this embodiment, the off-line simulation module 110 uses the observation time and the alternative observation time window to move on each overlapping time sequence CE1-CE3 respectively. For example, the length of the first observation time window may be 5 seconds, the length of the first alternative observation time window may be 15 seconds, and the length of the second alternative observation time window may be 20 seconds. Therefore, at the same observation time point of an overlapping time sequence, the observed crossing numbers of using the first observation time window, the first alternative observation time window, and the second alternative observation time window may be different. By generating observation time windows of different lengths (for example, at least one short observation time window and one long observation time window), the present disclosure can be applied to environments with rapid and slow changes in the number of people, which will be described in detail later.

As shown in FIG. 3B, in step S317, the off-line simulation module 110 calculates the occurrence probability of various numbers of people relative to various crossing numbers in the observation time window based on the multiple crossing numbers obtained from the overlapping time sequences, and generates an estimated people table based on the occurrence probability of various numbers of people relative to various crossing numbers in the observation time window. In particular, the off-line simulation module 110 generates a dedicated estimated people table for each observation time window. For example, when one observation time window and three alternative observation time windows are used, the off-line simulation module 110 will generate four different estimated people tables.

In some embodiments, for different numbers of people corresponding to each overlapping time sequence, the off-line simulation module 110 counts each crossing number obtained to generate the number of occurrences of each crossing number, and calculates the occurrence probability of each crossing number according to the number of occurrences of each crossing number. Afterward, the off-line simulation module 110 generates an estimated people table based on the number of people corresponding to each overlapping time sequence and the occurrence probability of each crossing number obtained from each overlapping time sequence.

Table 1 and Table 2 are used below as examples of tables for estimating the number of people.

| | the number of people | | |
|---|---|---|---|
| crossing numbers | 1 | 2 | 3 |
| 3 | 1 | 0 | 0 |
| 4 | 2 | 1 | 0 |
| 5 | 0 | 1 | 0 |
| 6 | 0 | 1 | 2 |
| 7 | 0 | 0 | 1 |

The Table 1 above is used to illustrate the example of FIG. 6. As shown in FIG. 6, when the number of virtual persons is 1, the number of 3 crossings observed within the length of one observation time window VW is one, that is, the observation time window VW at the observation time point 620, and the number of 4 crossings observed within the length of one observation time window VW is two, that is, the observation time window VW at the observation time points 610, 630. When the number of virtual persons is 2, the number of 3 crossings observed within the length of one observation time window VW is zero and the number of 4 crossings observed within the length of one observation time window VW is one, that is, the observation time window VW at the observation time point 630, and the number of 5 crossings observed within the length of one observation time window VW is one, that is, the observation time window VW at the observation time point 620, and the number of 6 crossings observed within the length of one observation time window VW is one, that is, the observation time window VW at the observation time point 610. When the number of virtual persons is 3, the number of 3, 4, and 5 crossings observed within the length of one observation time window VW is zero and the number of 6 crossings observed within the length of one observation time window VW is two, that is, the observation time window VW at the observation time points 610, 620, and the number of 7 crossings observed within the length of one observation time window VW is one, that is, the observation time window VW at the observation time point 630. According to the above observation results, the off-line simulation module 110 can generate the above Table 1.

TABLE 2

the number of people

| crossing numbers | 1 | 2 | 3 |
|---|---|---|---|
| 3 | 100% | 0% | 0% |
| 4 | 66.7% | 33.3% | 0% |
| 5 | 0% | 100% | 0% |
| 6 | 0% | 33.3% | 66.7% |
| 7 | 0% | 0% | 100% |

According to the statistics in Table 1, the off-line simulation module 110 may further convert the occurrence ratio of various numbers of people relative to different numbers of crossings into percentages, and generate an estimated people table as shown in Table 2. As shown in Table 2 above, for the number of crossings is equal to 3 times, it is only observed on the first overlapping time sequence CE1 corresponding to one person, and therefore the off-line simulation module 110 can calculate that the probability of only one virtual person passing through any virtual signal path is 100%.

For the number of crossings is equal to 4 times, it is observed twice on the first overlapping time sequence CE1 corresponding to one person and once on the third observation time point 630 of the second overlapping time sequence CE2 corresponding to two persons, and therefore the off-line simulation module 110 can calculate that the probability of only one virtual person passing through any virtual signal path is 66.7%, and the probability of two virtual persons passing through any virtual signal path is 33.3%.

For the number of crossings is equal to 5 times, it is only observed on the second overlapping time sequence CE2 corresponding to the two persons, and therefore the off-line simulation module 110 can calculate that the probability of two virtual persons passing through any virtual signal path is 100%.

For the number of crossings is equal to 6 times, it is observed once on the second overlapping time sequence CE2 corresponding to two persons and twice on the third overlapping time sequence CE3 corresponding to three persons, and therefore the off-line simulation module 110 can calculate that the probability of two virtual persons passing through any virtual signal path is 33.3%, and the probability of three virtual persons passing through any virtual signal path is 66.7%.

For the number of crossings is equal to 7 times, it is only observed on the third overlapping time sequence CE3 corresponding to the three persons, and therefore the off-line simulation module 110 can calculate that the probability of three virtual persons passing through any virtual signal path is 100%.

By the above steps, the present disclosure can generate an estimated people table (i.e., Table 2 above) indicating the occurrence probability of various numbers of people relative to various numbers of crossings within the observation time window for the simulation environment F2, and the estimated people table corresponds to an observation time window with a specific length. Therefore, in the actual environment F1, the present disclosure can directly apply the estimated people table generated by the simulation environment F2 to the crossing event time sequence obtained in the environment F1 (described in detail later). Accordingly, the present disclosure can significantly reduce the computing resources of the people counting device 123.

In particular, when the number of people in environment F1 changes rapidly, it is appropriate to use the estimated people table corresponding to the shorter observation time window for detection. Conversely, when the number of people in environment F1 changes slowly, it is appropriate to use the estimated people table corresponding to the longer observation time window for detection. Therefore, the off-line simulation module 110 disclosed in the present disclosure can set at least one alternative observation time window length and generate an alternative estimated people table corresponding to alternative observation time window length (described in detail later).

The above paragraphs describe the simulation process executed by the off-line simulation module 110 of the present disclosure in the simulation environment F2, and the following paragraphs will describe the execution process in the actual environment F1.

As shown in FIG. 3A, in step S320, at least one set of sensors 121(1)-121(s), 122(1)-122(t) continuously senses the wireless signal on its sensing path and measures the signal strength of the wireless signal. Specifically, when one person in the environment F1 passes through the sensing path, the signal strength of the wireless signal received by the sensors 122(1)-122(t) at the receiving terminal will attenuate. According to the attenuation degree, the people counting device 123 can determine whether one person passes by.

In some embodiments, the sensing path is a path for transmitting signals between a transmitting terminal and a receiving terminal.

In step S330, the people counting device 123 continuously extracts the crossing event time sequence of the persons P1-Po relative to the sensing path when they move in the environment F1 according to the signal strength.

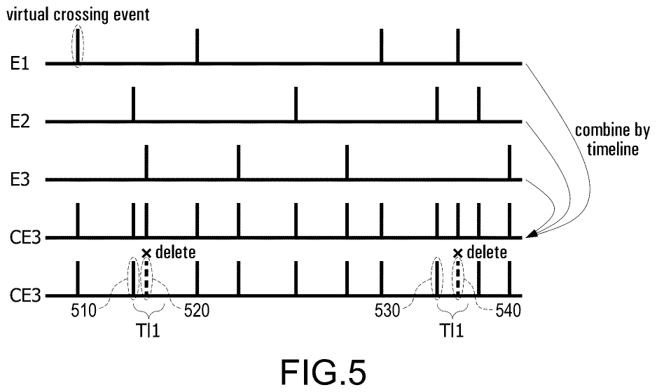

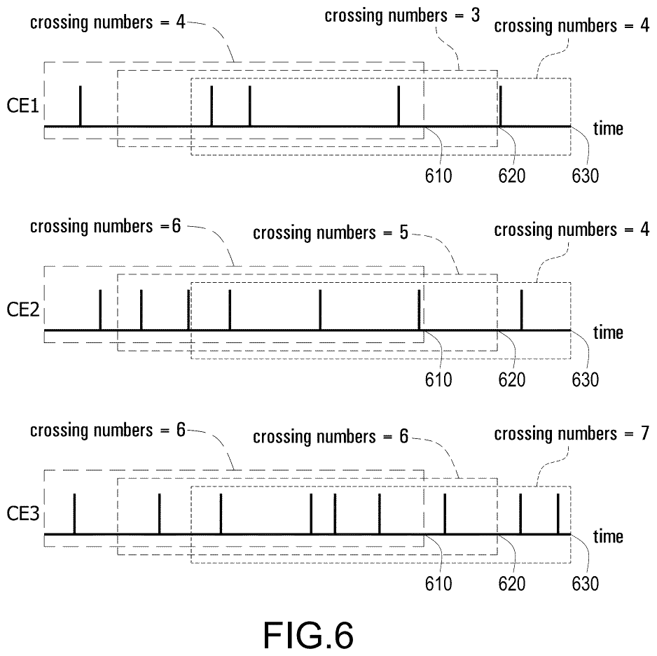

The following further describes how to generate the crossing event time sequence. Please refer to FIG. 7A, which shows a flowchart of a plurality of sub-steps (S331-S332) included in one step (S330) of a method for counting people based on wireless signals in some embodiments of the present disclosure.

As shown in FIG. 7A, in step S331, the people counting device 123 may continuously detect whether the signal strength changes relative to a strength threshold.

In step S332, the people counting device 123 may detect each event in which the signal strength significantly changes relative to a preset strength threshold as an actual crossing event, and generate a crossing event time sequence of the persons P1-Po relative to the sensing path when walking in the environment F1 according to all the actual crossing events and multiple actual occurrence times of each actual crossing event. In this embodiment, each actual occurrence time indicates the time point when the corresponding actual crossing event is detected.

When no person passes through the sensing path, the signal strength will continue to be greater than the preset strength threshold. In the first embodiment, when the people counting device 123 detects that the signal strength changes from greater than the strength threshold to less than the strength threshold, it determines that a person passes through the sensing path and records an actual crossing event. In the second embodiment, when the people counting device 123 detects that the signal strength is less than the strength threshold for a period of time, it determines that a person passes through the sensing path or stays on the sensing path and records an actual crossing event. In the third embodiment, when the people counting device 123 detects that the signal strength changes from greater than the strength threshold to less than the strength threshold, and then changes from less than the strength threshold to greater than the strength threshold, it determines that a person passes through the sensing path and records an actual crossing event. In the fourth embodiment, when the people counting device 123 detects that the signal strength changes from less than the strength threshold to greater than the strength threshold, it determines that a person passes through the sensing path and records an actual crossing event.

The following describes how to generate a crossing event time sequence by combining an actual example with the first embodiment described above. Please refer to FIG. 7B, which shows a schematic diagram of converting signal strength (LPS1) into a crossing event time sequence (RE1) in some embodiments of the present disclosure. As shown in FIG. 7B, in the relationship diagram between the CSI value and the number of packets of the received wireless signal, the signal strength LPS1 may be generated by the original signal strength OS1 (e.g., CSI value) of the wireless signal detected by the sensor at the receiving terminal through any low-pass filtering process (e.g., Chebyshev filter).

The people counting device 123 can detect that the signal strength LPS1 changes from being greater than a strength threshold THR1 to being less than the strength threshold THR1 three times, and regards these three changes from being greater than a strength threshold THR1 to being less than the strength threshold THR1 as actual crossing events 710-730.

Afterward, the people counting device 123 can generate a crossing event time sequence RE1 of the persons P1-Po walking in the environment F1 relative to the sensing path according to the actual crossing events 710-730 and the actual occurrence time of each of the actual crossing events 710-730. The three impulses in the crossing event time sequence RE1 are the actual crossing events 710-730, and the corresponding three time points are the actual occurrence time of each of the actual crossing events 710-730.

As shown in FIG. 3A, in step S340, the people counting device 123 uses an observation time window to count at least one crossing number in the crossing event time sequence RE1 relative to the observation time window at at least one detection time point. In one embodiment, the observation time window used by the people counting device 123 in step S340 is the same as the observation time window VW used by the off-line simulation module 110 in the aforementioned step S315.

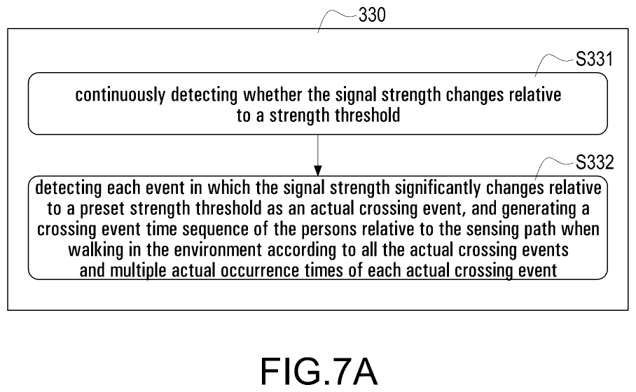

The following further describes how to generate the crossing number from the crossing event time sequence RE1. Please refer to FIG. 8, which shows a flowchart of a plurality of sub-steps (S341-S342) included in another step (S340) of a method for counting people based on wireless signals in some embodiments of the present disclosure.

As shown in FIG. 8, in step S341, the people counting device 123 generates an observation time window corresponding to the above observation time window length, and moves the observation time window on the crossing event time sequence according to at least one detection time point. In particular, the present disclosure uses the collected data to estimate the number of people in the environment F1, and therefore the last detection time point may be regarded as the current time point, but it is not limited to this.

In some embodiments, the people counting device 123 can use the last end of the observation time window (i.e., the time point at which the observation ends) as a reference to move the observation time window to at least one detection time point. In some embodiments, there is also a specific time interval (e.g., 1 second) between the detection time point and the adjacent detection time point, and this time interval is determined by the system sensitivity of the people counting device 123 (i.e., the precision of the detection).

In step S342, the people counting device 123 obtains at least one crossing number of an actual crossing event in an observation time window at at least one detection time point of the crossing event sequence.

In some embodiments, at least one crossing number indicates the total number of all actual crossing events in the observation window at the corresponding detection time point. In some embodiments, the detection time point is the time point at which the signal strength is sampled.

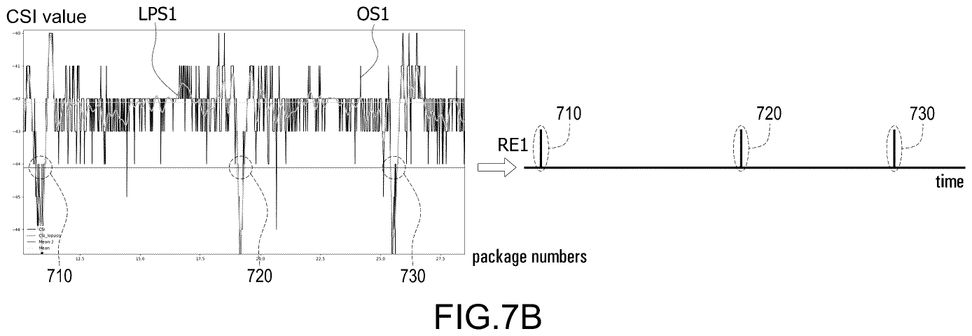

The following is an actual example of how to obtain the number of crossings. Please refer to FIG. 9, which shows a schematic diagram of a crossing event time sequence (RE2) in some embodiments of the present disclosure. As shown in FIG. 9, in the crossing event time sequence RE2, the people counting device 123 can calculate the number of actual crossing events (i.e., all impulses in the observation time window TW1) in the observation time window TW1 at the detection time point T1, and generate the number of crossings (in the embodiment of FIG. 9, 5 times). Afterward, the people counting device 123 moves the observation time window backward according to the time interval. Whenever the observation time window TW1 moves, the people counting device 123 can obtain the number of crossings in the observation time window TW1 at the next detection time point in the same manner. Moreover, the last detection time point does not exceed the current time point.

As shown in FIG. 3A, in step S350, the people counting device 123 queries the estimated people table which is pre-established by the off-line simulation module 110 according to at least one crossing number observed in step S340 to directly obtain the actual number of people in the environment F1. In this embodiment, the people counting device 123 uses the number of people in the estimated people table that meets at least one crossing number and has the highest occurrence probability as the actual number of people in the environment F1. For example, if the number of crossings observed by the people counting device 123 in step S340 is 3 times, after querying the estimated people table, the actual number of people can be directly determined to be 1 person (100%). If the number of crossings observed by the people counting device 123 in step S340 is 6 times, after querying the estimated people table, the actual number of people can be directly determined to be 3 people (since 66.7% representing 3 people is greater than 33.3% representing 2 people and 0% representing 1 person).

The above embodiments are described by taking a single observation time window as an example. However, as mentioned above, in order to be applicable to environments where the number of people changes rapidly and slowly, the present disclosure may simultaneously use multiple observation time windows of different lengths (e.g., at least one short observation time window (e.g., 5 seconds) and at least one long observation time window (e.g., 20 seconds)). In this condition, the present disclosure needs to first calculate the people change index corresponding to each observation time window by the number of crossings in the environment, and then use the people change index to determine the weighting of each observation time window, or decide which observation time window to use for the corresponding estimated people table. In the following embodiments, the embodiment using multiple observation time windows will be described.

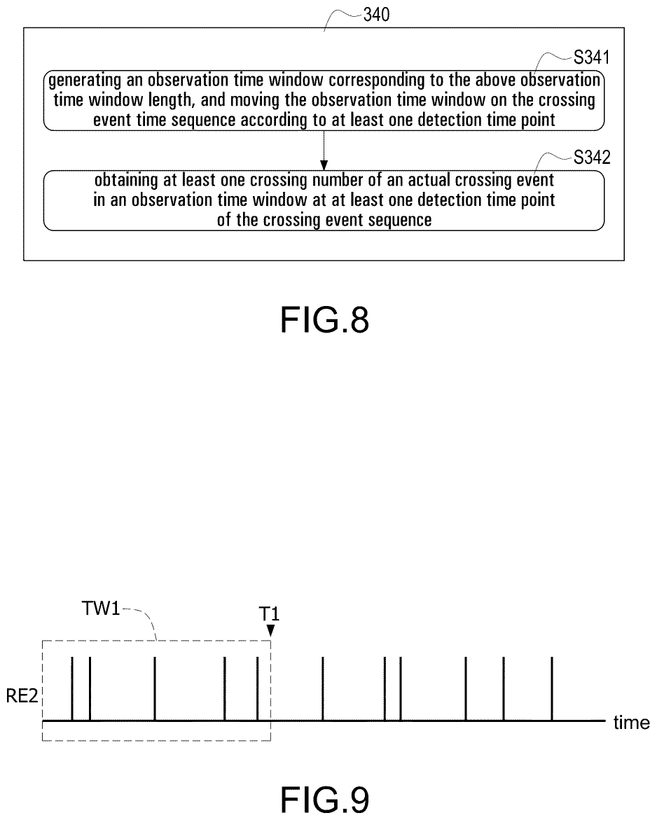

Please refer to FIG. 10, which shows a flowchart of a plurality of further steps (S1010-S1050) of a method for counting people based on wireless signals in some embodiments of the present disclosure.

As shown in FIG. 10, in step S1010, the off-line simulation module 110 executes a simulation algorithm based on the environmental parameters of the environment F1 to generate at least one alternative observation time window corresponding to at least one alternative observation time window length and at least one alternative estimated people table corresponding to at least one alternative observation time window.

In particular, the methods of generating the alternative observation time window and the alternative estimated people table are similar to the methods of generating the above-mentioned observation time window and estimated people table, which will not be further described her.

In step S1020, the people counting device 123 uses the alternative observation time window to count at least one alternative crossing number in the crossing event time sequence relative to the alternative observation time window at at least one detection time point.

In particular, the method of generating the at least one alternative crossing number is similar to the method of generating the above-mentioned crossing number, which will not be further described here.

In step S1030, the people counting device 123 respectively queries the estimated people table corresponding to the observation time window and the alternative estimated people table corresponding to the alternative observation time window according to at least one crossing number corresponding to the observation time window and at least one alternative crossing number corresponding to alternative observation time window so as to obtain the estimated people in the observation time window and alternative estimated people in the alternative observation time window.

In some embodiments, the people counting device 123 may use at least one crossing number to look up the estimated people table to obtain the number of people with the highest occurrence probability corresponding to the at least one crossing number as the estimated number of people in the observation time window.

In some embodiments, the people counting device 123 may use at least one alternative crossing number to look up the alternative estimated people table corresponding to the alternative observation time window to obtain the number of people with the highest occurrence probability corresponding to the alternative crossing number as the alternative estimated number of people in the alternative observation time window.

In particular, the method of generating the alternative estimated number of people is similar to the method of generating the estimated number of people, which will not be further described here.

In step S1040, the people counting device 123 calculates the weightings of the observation time window and alternative observation time window from at least one crossing number and at least one alternative crossing number. When there are multiple alternative observation time windows, the people counting device 123 calculates the weightings of the observation time window and multiple alternative observation time windows respectively.

In some embodiments, the people counting device 123 calculates a plurality of first standard deviations of multiple crossing numbers obtained before a specific detection time point, and calculates a standard deviation of the plurality of first standard deviations as a people change index of the alternative observation time window.

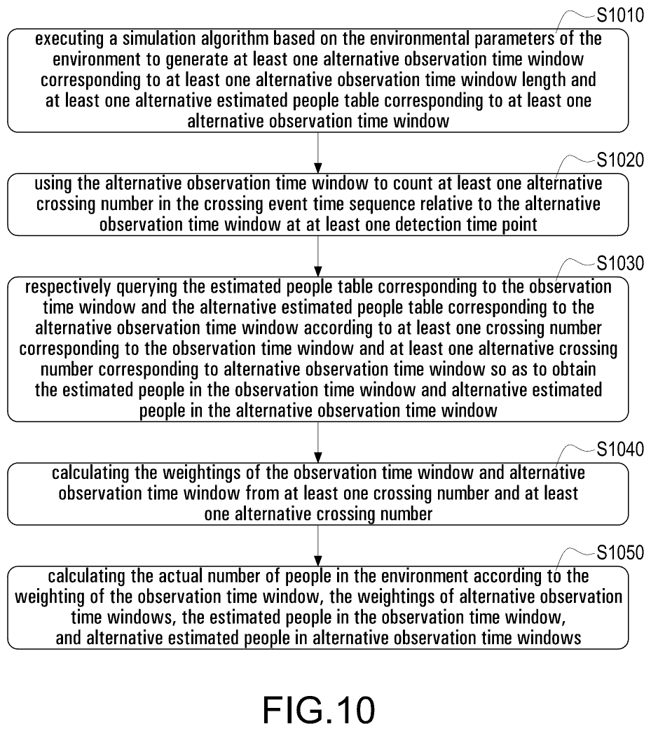

The following is a practical example to illustrate how to calculate the people change index. Refer to FIG. 11, which is a schematic diagram of a crossing event time sequence (RE2) in some other embodiments of the present disclosure. As shown in FIG. 11, it is assumed that the observation time window length is N seconds and the observation time window moves sequentially to the time points T₁-T_{M+P-1} (M may be pre-set by the user and corresponds to the number of data to be obtained for the standard deviation, and M+P−1 is the number of movement of the observation time window before the specific detection time point). The people counting device 123 can use this observation time window to detect multiple crossing numbers C₁-C_{M+P-1} in the observation time window at the time point T₁-T_{M+P-1} (TM+P−1 is the last detection time point). In particular, the present disclosure uses the observation time window to observe the past data, and therefore T_{M+P-1} represents the current time point, and the people counting device 123 observes from the current time point forward.

Afterward, the people counting device 123 can extract the first part (i.e., the multiple crossing numbers C₁-C_{M}) from the multiple crossing numbers C₁-C_{M+P-1}, and calculate the standard deviation V₁ of the multiple crossing numbers C₁-C_{M}, and then extract the second part (i.e., the multiple crossing number C₂-C_{M+1}) from the multiple crossing numbers C₁-C_{M+P-1}, and calculate the standard deviation V₂ of the multiple crossing numbers C₂-C_{M+1}. Similarly, the people counting device 123 can calculate the standard deviations V₃-V_{P} of the third part to the Pth part of the multiple crossing numbers C₁-C_{M+P-1} in the same manner. Afterward, the people counting device 123 can calculate the standard deviation of the multiple standard deviations V₁-V_{P} as the people change index SD1 of the observation time window at the specific detection time point (i.e., T_{M+P-1}).

In particular, the alternative people change index corresponding to the alternative observation time window is also calculated in the same calculation method above, which will not be further described here.

In some embodiments, the people counting device 123 alternately sets the minimum people limit (for example, one person) and the maximum people limit (for example, equal to the above-mentioned simulated people limit) for multiple cycles of simulation time, and the minimum people limit and the maximum people limit respectively indicate the upper limit of the number of virtual persons in the simulation environment F2.

In some embodiments, the people counting device 123 establishes a people change schedule for the environment F1 of known size, and alternative people change schedules are planned as the minimum number of people (1 person) at the first sampling (e.g., the 0th second), the upper limit of the number of people at the second sampling (e.g., the 1st second), the minimum number of people at the third sampling (e.g., the 2nd second), and so on, and continue for a specified period of time (e.g., 52 hours). Afterward, the people counting device 123 uses a people change time window with a specified length, and obtains the people change index at each detection time point in the people change time window based on the same simulation method as above. Afterwar, the people counting device 123 can perform numerical statistics on multiple people change indexes of the people change time window, and obtain the people change index corresponding to a specific percentile (e.g., the 95th percentile) as the maximum people change index.

In this embodiment, the people counting device 123 uses the shortest time window in the observation time window and alternative observation time windows as the shortest time window, and then uses the observation time window and alternative observation time windows except the shortest time window as longer time windows.

In some embodiments, the people counting device 123 may divide the people change index of the shortest time window by the maximum people change index to generate the weighting of the shortest time window. Afterward, the people counting device 123 may calculate the difference between 1 and the weighting of the shortest time window, and calculate the product of this difference and the length of each longer time window. Afterward, the people counting device 123 may divide the product obtained from each longer time window by the sum of multiple longer time windows to generate the weighting of each longer time window.

Returning to FIG. 10, in step S1050, the people counting device 123 calculates the actual number of people in the environment F1 according to the weighting of the observation time window, the weightings of alternative observation time windows, the estimated people in the observation time window, and alternative estimated people in alternative observation time windows.

In some embodiments, the people counting device 123 calculates the product between the weighting of the observation time window and the estimated people, and then calculates the product between the weightings of alternative observation time windows and alternative estimated people, and finally performs a ceiling operation on the sum of all products to generate the actual number of people in the environment F1.

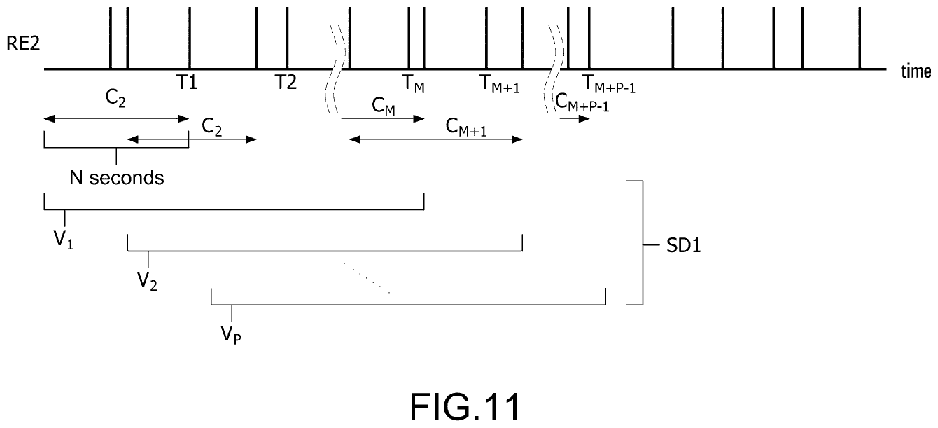

The following is a practical example to illustrate how to calculate the actual number of people. Please refer to FIG. 12, which shows a schematic diagram of a crossing event time sequence (RE2) in some other embodiments of the present disclosure. As shown in FIG. 12, it is assumed that the people counting device 123 uses a longer observation time window TW1 and a shorter observation time window TW2, and both observation time windows TW1-TW2 have moved to the detection time point T_{M+P-1}. At this time, the people counting device 123 can detect the crossing numbers of each crossing event in the observation time windows TW1-TW2.

As shown in FIG. 12, the crossing numbers of the crossing event in the observation time window TW1 is 5, and the crossing numbers of the crossing event in the observation time window TW2 is 2. It is assumed that the people counting device 123 obtains the corresponding estimated number of people from the estimated people table corresponding to the observation time window TW1 as 2 people, and the estimated number of people obtained from the estimated people table corresponding to the observation time window TW2 is 1 person. Therefore, the people counting device 123 can calculate the weightings of the observation time windows TW1-TW2 in the above manner.

It is assumed that the weightings of the observation time windows TW1-TW2 are 2/3 and 1/3 respectively, the people counting device 123 can calculate the product between the weighting 2/3 and the estimated number of people as 2, and then calculate the product between the weighting 1/3 and the estimated number of people as 1. Afterward, the people counting device 123 can perform a ceiling operation on the sum of these products (i.e., 5/3) to generate the actual number of people in the environment F1 (i.e., 2 people).

In particular, although one observation time window TW1 and one alternative observation time window TW2 are used as examples, in actual application, the present disclosure also calculates the actual number of people in the environment F1 in the same calculation method when there are more alternative observation time windows, which will not be further described here.

As mentioned above, a shorter observation time window is more suitable for estimating the number of people when the number of people changes rapidly, while a longer observation time window is more suitable for estimating the number of people when the number of people changes slowly. Therefore, the present disclosure can set respective weightings for observation time windows of different lengths according to change degrees of the number of people in environment F1 through the above steps. Therefore, the present disclosure can query each estimated people table corresponding to each observation time window according to the weighting of each observation time window, thereby more accurately calculating the actual number of people in environment F1.

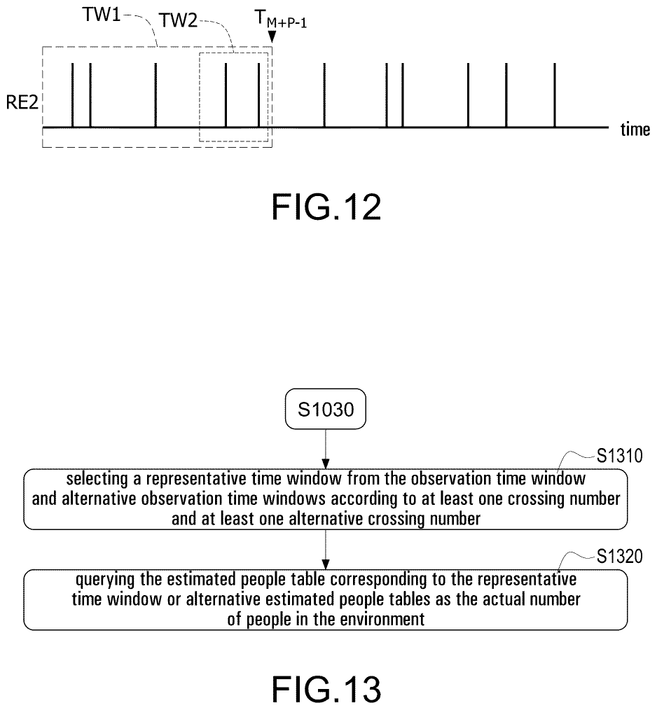

Another embodiment using multiple observation time windows of different lengths will be described below. Please refer to FIG. 13, which shows a flowchart of a plurality of further steps (S1310-S1320) of a method for counting people based on wireless signals in some other embodiments of the present disclosure.

As shown in FIG. 13, after executing step S1030, the people counting device 123 further executes step S1310. In step S1310, the people counting device 123 selects a representative time window from the observation time window and alternative observation time windows according to at least one crossing number and at least one alternative crossing number.

In some embodiments, the people counting device 123 can use multiple crossing numbers obtained before a specific detection time point to calculate the multiple crossing number changes during this period (for example, summing up n consecutive crossing numbers as a crossing count change), and remove noise from the consecutive multiple crossing number changes (for example, using a Hampel filter), and finally calculate the standard deviation of the multiple denoising results to obtain the people change index in the observation time window at the specific detection time point.

In some embodiments, when multiple detection time points are included, the people counting device 123 respectively calculates the denoising results of multiple crossing number changes obtained before each detection time point, and calculates multiple standard deviations of these denoising results as multiple people change indexes of the observation time window at multiple detection time points.

In some embodiments, for alternative observation time windows, the people counting device 123 uses multiple alternative crossing numbers obtained before the specific detection time point to calculate the changes in multiple alternative crossing number changes during this period (for example, summing up n consecutive alternative crossing numbers as one alternative crossing number change), and performs denoising processing on the consecutive multiple alternative crossing number changes, and calculates the standard deviation of the multiple denoising results to obtain alternative people change indexes for alternative observation time windows at the specific detection time point.

In some embodiments, when multiple detection time points are included, the people counting device 123 calculates the denoising results of multiple alternative crossing number changes obtained before each detection time point, and calculates multiple standard deviations of these denoising results as multiple alternative people change indexes of the alternative observation time window at multiple detection time points.

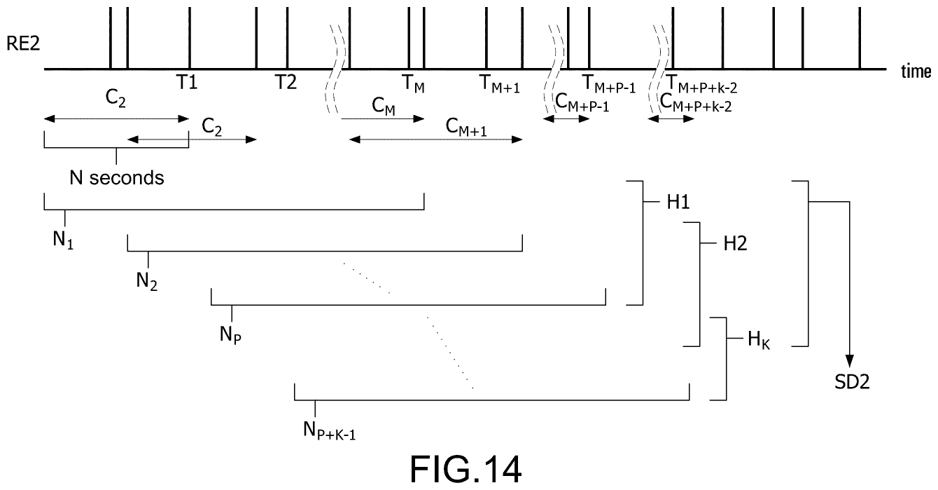

The following is another practical example to illustrate how to calculate the people change index. Please refer to FIG. 14, which shows a schematic diagram of a crossing event time sequence (RE2) in some other embodiments of the present disclosure. As shown in FIG. 14, it is assumed that the length of the observation time window is N seconds and there are multiple detection time points T₁-T_{M+P+K-2} on the crossing event time sequence RE2 (M may be preset by the user and corresponds to the number of data to be obtained for the standard deviation, and M+P+K−2 is the number of movement of the observation time window before the specific detection time point, and K is the number of multiple parts taken from the crossing number change N₁-N_{P+K-1} described in the subsequent paragraphs), the people counting device 123 can detect multiple crossing numbers C₁-C_{M+P+K-2} in the observation time window on the detection time point T₁-T_{M+P+K-2} (T_{M+P+K-2} is the last detection time point, that is, the current time point).

Afterward, the people counting device 123 can extract the first part (i.e., the crossing numbers C₁-C_{M}) from the crossing numbers C₁-C_{M+P+K-2}, and calculate the first crossing number change N₁ (e.g., summing up the crossing numbers C₁-C_{M}) during this time interval, and then extract the second part (i.e., the crossing numbers C₂-C_{M+1}) from the crossing numbers C₁-C_{M+P+K-2}, and calculate the second crossing number change N₂ (e.g., summing up the crossing numbers C₂-C_{M+1}) during this time interval. Similarly, the people counting device 123 can calculate the crossing number change N₃-N_{P+K-1} from the third part to the P+K−1 part of the multiple crossing numbers C₁-C_{M+P+K-2} in the same manner.

Afterward, the people counting device 123 can extract the first part (i.e., the multiple crossing number changes N₁-N_{P}) from the multiple crossing number changes N₁-N_{P+K-1}, and perform the denoising processing on the multiple crossing number changes N₁-N_{P} to obtain the denoising result H₁, and then extract the second part (i.e., the multiple crossing number changes N₂-N_{P+1}) from the multiple crossing number changes N₁-N_{P+K-1}, and perform the denoising processing on the multiple crossing number changes N₂-N_{P+1} to obtain the denoising result H₂. Similarly, the people counting device 123 can calculate the denoising results H₃-H_{K} of the third part to the Kth part of the multiple crossing number changes N₁-N_{P+K-1} in the same manner.

Afterward, the people counting device 123 further calculates the standard deviation of the plurality of denoising results H₁-H_{K} as the people change index SD2 of the observation time window at the detection time point (i.e., the current time point T_{M+P+K-2}).

By analogy, for different detection time points, the people counting device 123 may also calculate the corresponding people change index in the same calculation method. In particular, the people change index of each alternative observation time window at each detection time point is also calculated in the same calculation method as above, which will not be further described here.

In some embodiments, the plurality of detection time points include a current time point, which indicates a time point at which the actual number of people needs to be detected. In some embodiments, the people counting device 123 selects one of the observation time window and the at least one alternative observation time window as the people change time window (e.g., selectable by the user).

In some embodiments, for the people change time window, the people counting device 123 may select the detection time point whose corresponding people change index is greater than the index threshold and closest to the current time point (t) from any detection time point before the current time point as the event time point (x), and calculate the time difference (d=x−t) between the event time point and the current time point. Afterward, the people counting device 123 may calculate the product (i.e., d*r) between the time difference and a conversion ratio (r, such as 50%) of a preset early conversion time window, and select one of the observation time window and the alternative observation time window, which is not greater than the calculated product and has a length closest to the product (i.e., the difference between the length and the product is the smallest) as the representative time window.

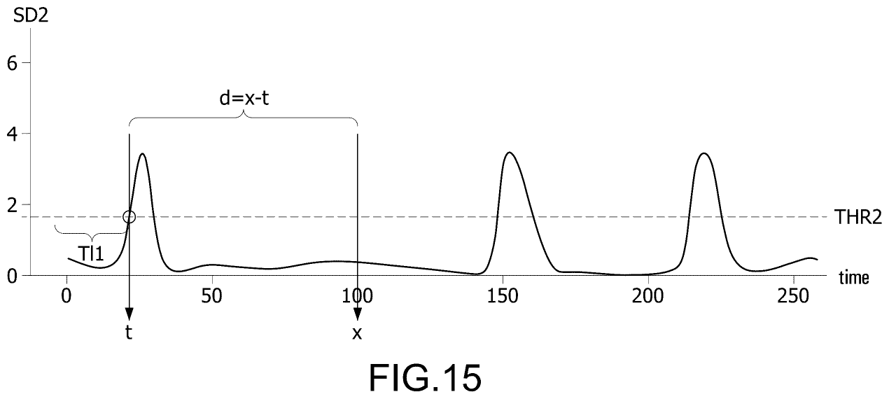

The following is a practical example to illustrate the selection of the representative time window. Please refer to FIG. 15, which shows a diagram of a relationship between a people change index (SD2) and multiple detection time points in some embodiments of the present disclosure. As shown in FIG. 15, it is assumed that the current time point is x, the people counting device 123 determines that the people change index SD2 is greater than the index threshold THR2 and the detection time point closest to the current time point x is the event time point t.

In particular, when the people counting device 123 detects that there are two adjacent time points and the people change index SD2 is greater than the index threshold THR2, the time point closer to the current time point x will be used as the event time point t only when the time difference between the two time points is less than the interval threshold TI1. If there are two adjacent time points and the people change index SD2 is greater than index threshold THR2, the people counting device 123 will ignore the latter time point and use the former time point as the event time point t when the time difference between the two time points is less than the interval threshold TI1.

Afterward, the people counting device 123 can calculate the time difference d between the current time point x and the event time point t, and calculate the product (i.e., d*r) between the time difference d and the preset conversion ratio (r, such as 50%), and select one of the observation time windows, which is not greater than the calculated product and has a length closest to the product as the representative time window from the observation time window and alternative observation time window. For example, if the conversion ratio is 100% and the time difference d is 20 seconds, the people counting device 123 can select the one of the observation time window and the alternative observation time window, which is not greater than 20 seconds and has a length closest to 20 seconds as the representative time window (i.e., the length of the representative time window <=d*r). For another example, if the conversion ratio is 50% and the time difference is 20 seconds, the people counting device 123 can select the one of the observation time window and the alternative observation time window, which is not greater than 10 seconds and has a length closest to 10 seconds as the representative time window.

Returning to FIG. 13, in step S1320, the people counting device 123 queries the estimated people table corresponding to the representative time window or alternative estimated people tables as the actual number of people in the environment F1.

By the above steps, the present disclosure can select the most suitable one for the current people change from the observation time window and/or alternative observation time window of different lengths as the representative time window according to the change in the number of people. Therefore, the present disclosure can obtain the actual number of people in the environment F1 from the estimated people table corresponding to the representative time window, thereby increasing the estimation accuracy.

In summary, the present disclosure can simulate the actual environment and actual people in advance to generate an estimated people table, and generate a crossing event time sequence according to the signal strength detected in the actual environment, and then use an observation time window of a specific length to obtain crossing numbers at each time point, and use the estimated people table to convert multiple crossing numbers into the actual number of people in the actual environment. In addition, the present disclosure can also use multiple observation time windows of different lengths and their corresponding estimated people tables, and calculate the weighting of each observation time window in a statistical manner, and then combine the weighting of each observation time window and the corresponding estimated people table to calculate the actual number of people in the actual environment. On the other hand, the present disclosure can also select the optimal length of the representative time window from the multiple observation time windows in a statistical manner, and use the estimated people table corresponding to the representative time window to obtain the actual number of people in the actual environment. Therefore, the present disclosure does not need to install sensors in a location that is not conducive to sensing, and is not limited by high-cost cameras, network bandwidth and computing resources, and will not be unable to estimate the number of people since the people in the environment do not carry any smart devices with Wi-Fi functions.

Although the present disclosure has been described with reference to the preferred embodiment thereof, it will be understood that the present disclosure is not limited to the details thereof. Various substitutions and modifications have been suggested in the foregoing description, and others will occur to those of ordinary skill in the art. Therefore, all such substitutions and modifications are intended to be embraced within the scope of the present disclosure as defined in the appended claims.

What is claimed is:

1. A system for people counting based on wireless signals applied in an environment, comprising:
an off-line simulation module, configured to execute a simulation algorithm, the simulation algorithm configured to perform simulation based on an environmental parameter of the environment and generate an estimated people table, wherein the estimated people table is configured to record occurrence probabilities of various people in the environment relative to various crossing numbers within an observation time window; and
a real-time detection module, comprising at least one set of sensor and a people counting device, the at least one set of sensor disposed in the environment and comprising a transmitting terminal and a receiving terminal, the transmitting terminal configured to transmit a wireless signal and the receiving terminal configured to receive the wireless signal so as to measure a signal strength of the wireless signal, the people counting device configured to receive the signal strength measured by the at least one set of sensor, and perform the following actions:
action (a): extracting a crossing event time sequence of a sensing path relative to the at least one set of sensor when a person moves in the environment according to the signal strength, wherein the crossing event time sequence is configured to record multiple time-based actual crossing events;
action (b): using the observation time window to count at least one crossing number in the crossing event time sequence relative to the observation time window at at least one detection time point; and
action (c): querying the estimated people table to obtain an actual number of people in the environment according to the at least one crossing number, wherein the people counting device is configured to use the number of people in the estimated people table that meets the at least one crossing number and has the highest occurrence probability as the actual number of people.

2. The system for people counting as claimed in claim 1, wherein the at least one set of sensor comprises a single transmitting terminal and a single receiving terminal, or a plurality of transmitting terminals and a single receiving terminal, or a single transmitting terminal and a plurality of receiving terminals.

3. The system for people counting as claimed in claim 1, wherein the environmental parameter comprises a size of the environment, a position of the at least one set of sensor in the environment, a simulation time of the simulation algorithm, a simulated people limit, a length of the observation time window, a sampling frequency, a walking speed of a virtual person, and a turning probability.

4. The system for people counting as claimed in claim 3, wherein the off-line simulation module is configured to perform the following actions in the simulation algorithm:
generating a simulated environment based on the size of the environment and the position of the at least one set of sensor, and generating a plurality of virtual people corresponding to the simulated people limit, wherein the simulation environment has at least one virtual sensor generated based on the position of the at least one set of sensor, and the at least one virtual sensor is configured to transmit signals along at least one virtual signal path;
randomly generating a virtual moving path for each virtual person in the simulation environment based on the walking speed and the turning probability, and making the virtual people move along respective virtual moving paths at the walking speed within the simulation time;
recording a plurality of virtual crossing events according to the sampling frequency when each virtual person passes through the at least one virtual signal path to generate a crossing event simulation time sequence for each virtual person;
generating a plurality of overlapping time sequences corresponding to a plurality of numbers of people based on the crossing event simulation time sequence of each virtual person, wherein the plurality of numbers of people is not greater than the simulated people limit;
generating the observation time window corresponding to the length of the observation time window, and moving the observation time window on each of the overlapping time sequences according to a plurality of observation time points;
obtaining the crossing number of the virtual crossing event in the observation time window at each observation time point for each of the overlapping time sequences; and
calculating the occurrence probabilities of various numbers of people relative to various crossing numbers within the observation time window according to multiple crossing numbers obtained from each of the overlapping time sequences, and generating the estimated people table based on the occurrence probabilities of various numbers of people relative to various crossing numbers within the observation time window.

5. The system for people counting as claimed in claim 3, wherein the people counting device is configured to perform the following actions in action (b):
generating the observation time window corresponding to the length of the observation time window, and moving the observation time window on the crossing event time sequence according to the at least one detection time point; and
obtaining the at least one crossing number of the actual crossing event in the observation time window at the at least one detection time point of the crossing event time sequence.

6. The system for people counting as claimed in claim 4, wherein the environmental parameter further comprises an alternative observation time window length; the simulation algorithm is further configured to generate an alternative observation time window corresponding to the alternative observation time window length, and generate an alternative estimated people table corresponding to the alternative observation time window length based on the environmental parameter.

7. The system for people counting as claimed in claim 6, wherein the people counting device is further configured to perform the following actions:
action (d): using alternative observation time windows to count at least one alternative crossing number in the crossing event time sequence relative to the alternative observation time windows at the at least one detection time point;
action (e): respectively querying the estimated people table corresponding to the observation time window and the alternative estimated people table corresponding to the alternative observation time window according to the at least one crossing number and the at least one alternative crossing number corresponding to the alternative observation time window to obtain an estimated number of people in the observation time window and an alternative estimated number of people in the alternative observation time window;
action (f): calculating the weighting of the observation time window and the weighting of the alternative observation time window based on the at least one crossing number and the at least one alternative crossing number; and
action (g): calculating the actual number of people in the environment based on the weighting of the observation time window, the weighting of the alternative observation time window, the estimated number of people in the observation time window, and the alternative estimated number of people in the alternative observation time window.

8. The system for people counting as claimed in claim 7, wherein the people counting device is further configured to perform the following actions after action (e):
selecting a representative time window from the observation time window and the alternative observation time window according to the at least one crossing number and the at least one alternative crossing number; and
querying the estimated people table or the alternative estimated people table corresponding to the representative time window to obtain the actual number of people in the environment.

9. The system for people counting as claimed in claim 8, wherein the people counting device is configured to perform the following actions in the action of selecting the representative time window:
calculating multiple crossing number changes based on the multiple crossing numbers observed at multiple detection time points in the observation time window, and calculating multiple alternative crossing number changes based on the multiple alternative crossing numbers observed at multiple detection time points in the alternative observation time window;
calculating multiple denoising results of the multiple crossing number changes, calculating a standard deviation of the multiple denoising results to obtain a people change index for the observation time window, and calculating multiple denoising results of the multiple alternative crossing number changes, calculating a standard deviation of the multiple denoising results to obtain an alternative people change index for the alternative observation time window;
recording a people change time point when the people change index exceeds a change threshold value, and recording an alternative people change time point when the alternative people change index exceeds the change threshold value;
calculating a first distance between the last time point of the people change time point and the current time, and calculating a second distance between the last time point of the alternative people change time point and the current time;
calculating a first product of the first distance and a conversion ratio, and calculating a second product of the second distance and the conversion ratio; and
obtaining the larger of the observation time window whose length is not greater than and closest to the first product and the alternative observation time window whose length is not greater than and closest to the second product as the representative time window.

10. The system for people counting as claimed in claim 1, wherein the people counting device is configured to perform the following actions in action (a):
detecting whether the signal strength changes relative to a strength threshold; and
regarding an event of detecting the signal strength change relative to the strength threshold as an actual crossing event, and generating the crossing event time sequence relative to the sensing path when the person walks in the environment according to all the actual crossing events and the multiple actual occurrence times of each of the actual crossing events.

11. A method for people counting based on wireless signals, applied to a system for people counting, the system for people counting comprising an off-line simulation module and a real-time detection module, the real-time detection module comprising a people counting device and at least one set of sensor disposed in an environment, the method comprising steps of:
step (a): executing, by the off-line simulation module, a simulation algorithm based on an environmental parameter of the environment to generate an estimated people table, wherein the estimated people table is configured to record occurrence probabilities of various people in the environment relative to various crossing numbers within an observation time window;
step (b): sensing, by the set of sensor, a wireless signal on a sensing path and measuring a signal strength of the wireless signal;
step (c): extracting, by the people counting device, a crossing event time sequence relative to the sensing path when a person moves in the environment according to the signal strength, wherein the crossing event time sequence is configured to record multiple time-based crossing events;
step (d): using, by the people counting device, the observation time window to count at least one crossing number in the crossing event time sequence relative to the observation time window at at least one detection time point; and
step (e): querying, by the people counting device, the estimated people table to obtain an actual number of people in the environment according to the at least one crossing number, wherein the people counting device is configured to use the number of people in the estimated people table that meets the at least one crossing number and has the highest occurrence probability as the actual number of people.

12. The method for people counting as claimed in claim 11, wherein the at least one set of sensor comprises a single transmitting terminal and a single receiving terminal, or a plurality of transmitting terminals and a single receiving terminal, or a single transmitting terminal and a plurality of receiving terminals.

13. The method for people counting as claimed in 11, wherein the environmental parameter comprises a size of the environment, a position of the at least one set of sensor in the environment, a simulation time of the simulation algorithm, a simulated people limit, a length of the observation time window, a sampling frequency, a walking speed of a virtual person, and a turning probability.

14. The method for people counting as claimed in 13, wherein the step (a) comprises steps of:
generating, by the off-line simulation module, a simulated environment based on the size of the environment and the position of the at least one set of sensor, and generating a plurality of virtual people corresponding to the simulated people limit, wherein the simulation environment has at least one virtual sensor generated based on the position of the at least one set of sensor, and the at least one virtual sensor is configured to transmit signals along at least one virtual signal path;
randomly generating, by the off-line simulation module, a virtual moving path for each virtual person in the simulation environment based on the walking speed and the turning probability, and making the virtual people move along respective virtual moving paths at the walking speed within the simulation time;
recording, by the off-line simulation module, a plurality of virtual crossing events according to the sampling frequency when each virtual person passes through the at least one virtual signal path to generate a crossing event simulation time sequence for each virtual person;
generating, by the off-line simulation module, a plurality of overlapping time sequences corresponding to a plurality of numbers of people based on the crossing event simulation time sequence of each virtual person, wherein the plurality of numbers of people is not greater than the simulated people limit;
generating, by the off-line simulation module, the observation time window corresponding to the length of the observation time window, and moving the observation time window on each of the overlapping time sequences according to a plurality of observation time points;
obtaining, by the off-line simulation module, the crossing number of the virtual crossing event in the observation time window at each observation time point for each of the overlapping time sequences; and
calculating, by the off-line simulation module, the occurrence probabilities of various numbers of people relative to various crossing numbers within the observation time window according to multiple crossing numbers obtained from each of the overlapping time sequences, and generating the estimated people table based on the occurrence probabilities of various numbers of people relative to various crossing numbers within the observation time window.

15. The method for people counting as claimed in 13, wherein the step (d) comprises steps of:
generating, by the people counting device, the observation time window corresponding to the length of the observation time window, and moving the observation time window on the crossing event time sequence according to the at least one detection time point; and
obtaining, by the people counting device, the at least one crossing number of the actual crossing event in the observation time window at the at least one detection time point of the crossing event time sequence.

16. The method for people counting as claimed in 14, wherein the environmental parameter further comprises an alternative observation time window length, and the step (a) further comprises a step of:
generating an alternative observation time window corresponding to the alternative observation time window length, and generating an alternative estimated people table corresponding to the alternative observation time window length based on the environmental parameter.

17. The method for people counting as claimed in 16, further comprising steps of:
step (f): using, by the people counting device, alternative observation time windows to count at least one alternative crossing number in the crossing event time sequence relative to the alternative observation time windows at the at least one detection time point;
step (g): respectively querying, by the people counting device, the estimated people table corresponding to the observation time window and the alternative estimated people table corresponding to the alternative observation time window according to the at least one crossing number and the at least one alternative crossing number corresponding to the alternative observation time window to obtain an estimated number of people in the observation time window and an alternative estimated number of people in the alternative observation time window;
step (h): calculating, by the people counting device, the weighting of the observation time window and the weighting of the alternative observation time window based on the at least one crossing number and the at least one alternative crossing number; and
step (i): calculating, by the people counting device, the actual number of people in the environment based on the weighting of the observation time window, the weighting of the alternative observation time window, the estimated number of people in the observation time window, and the alternative estimated number of people in the alternative observation time window.

18. The method for people counting as claimed in 17, wherein after the step (g) further comprises steps of:
selecting, by the people counting device, a representative time window from the observation time window and the alternative observation time window according to the at least one crossing number and the at least one alternative crossing number; and
querying, by the people counting device, the estimated people table or the alternative estimated people table corresponding to the representative time window to obtain the actual number of people in the environment.

19. The method for people counting as claimed in 18, wherein the step of selecting, by the people counting device, a representative time window from the observation time window and the alternative observation time window according to the at least one crossing number and the at least one alternative crossing number comprises steps as follows:
calculating multiple crossing number changes based on the multiple crossing numbers observed at multiple detection time points in the observation time window, and calculating multiple alternative crossing number changes based on the multiple alternative crossing numbers observed at multiple detection time points in the alternative observation time window;
calculating multiple denoising results of the multiple crossing number changes, calculating a standard deviation of the multiple denoising results to obtain a people change index for the observation time window, and calculating multiple denoising results of the multiple alternative crossing number changes, calculating a standard deviation of the multiple denoising results to obtain an alternative people change index for the alternative observation time window;
recording a people change time point when the people change index exceeds a change threshold value, and recording an alternative people change time point when the alternative people change index exceeds the change threshold value;
calculating a first distance between the last time point of the people change time point and the current time, and calculating a second distance between the last time point of the alternative people change time point and the current time;
calculating a first product of the first distance and a conversion ratio, and calculating a second product of the second distance and the conversion ratio; and
obtaining the larger of the observation time window whose length is not greater than and closest to the first product and the alternative observation time window whose length is not greater than and closest to the second product as the representative time window.

20. The method for people counting as claimed in 11, wherein the step (c) comprises steps of:
detecting, by the people counting device, whether the signal strength changes relative to a strength threshold; and
regarding, by the people counting device, an event of detecting the signal strength change relative to the strength threshold as an actual crossing event, and generating the crossing event time sequence relative to the sensing path when the person walks in the environment according to all the actual crossing events and the multiple actual occurrence times of each of the actual crossing events.
